(19) United States
(12) Patent Application Publication
(10) Pub. No.: US 2013/0001767 A1
(43) Pub. Date: Jan. 3, 2013

(54) PACKAGE AND METHOD FOR MANUFACTURING PACKAGE

(75) Inventor: Atsunori KAJIKI, Nagano-shi (JP)

(73) Assignee: Shinko Electric Industries Co., Ltd., Nagano-shi (JP)

(21) Appl. No.: 13/534,409

(22) Filed: Jun. 27, 2012

(30) Foreign Application Priority Data
Jun. 28, 2011 (JP) 2011-142843

(51) Int. Cl. H01L 23/498; H01L 21/56

(52) U.S. Cl. 257/734; 438/126; 257/E21.502; 257/E23.06

(57) ABSTRACT

A method for manufacturing a package, includes preparing a substrate having a first surface on which a connecting pad is formed, mounting a sacrificing material on the connecting pad, forming a package portion covering the first surface of the substrate, exposing the sacrificing material from a surface of the package portion, and removing the exposed sacrificing material from the side of the surface of the package portion, and forming an opening portion in the package portion on the connecting pad.

### CROSS-REFERENCE TO RELATED APPLICATION(S)

The present application claims the benefit of priority of Japanese Patent Application No. 2011-142843, filed on Jun. 28, 2011. The disclosures of the application are incorporated herein by reference.

### BACKGROUND

### Technical Field

The present disclosure relates to a package and a method for manufacturing the package.

U.S. Pat. No. 7,777,351 (Patent Document 1) discloses a method for manufacturing a package, including steps of forming a via in a package portion extending toward a connection portion by a laser drilling process, and filling the via with solder.

JP-A-2007-335907 (Patent Document 2) discloses a method for manufacturing a package, including a step of grinding a mold resin (package portion) in order to expose a test terminal.

### PATENT DOCUMENT

[Patent Document 1] U.S. Pat. No. 7,777,351 Specification (FIG. 2A, FIG. 2B, and FIG. 2C)
[Patent Document 2] JP-A-2007-335907 (FIG. 9)

There is a package on which a package portion for enclosing (or covering) an electronic component (semiconductor chip, chip capacitor and the like) mounted on a substrate is formed. A package into which a semiconductor chip is incorporated is referred to also as a semiconductor package (semiconductor device). Some packages themselves serve as base members. On such a package, another component (e.g., an electronic component or a package) may be mounted.

Upon mounting another component on a package and electrically connecting the mounted component and the package to each other, a connecting part (e.g., a connecting pad) of the package is bonded to that (e.g., a connecting bump) of the component. For example, in the case of a package having a substrate on which a connecting pad is formed, it is necessary for exposing the connecting pad that an opening portion communicating with the connecting pad is formed in a package portion. Thus, it is desired that the opening portion of the package maintains a desired shape and is formed with good positional accuracy.

Meanwhile, there is package-on-package (POP) technology for configuring a structure by mounting a semiconductor package (hereunder referred to as a top package) serving as an upper stage on a semiconductor package (hereunder referred to as a bottom package) serving as a lower stage. Hereinafter, a related-art manufacturing method for a bottom package is described with reference to FIGS. 1 and 2.

According to this manufacturing method for a bottom package, first, a substrate 2 on which wiring includes each connecting pad 1 is formed is prepared, as illustrated in FIG. 1. Then, a semiconductor chip 4 is mounted on the substrate 2 through an insulating layer 3 by, e.g., a flip-chip technique. Next, a package portion 6 is formed, in which the semiconductor chip 4 is enclosed with a mold resin. Then, laser light is irradiated onto the package portion 6. An opening portion 11X communicating with each connecting pad 1 is formed. Next, as illustrated in FIG. 2, a bonding material (auxiliary solder) 13 is formed on each connecting pad 1 by injecting solder into each opening portion 11X. Thus, a bottom package 12X is manufactured. Incidentally, e.g., the method disclosed in the above Patent Document 1 can be used to form each opening portion 11X using a laser L (see FIG. 1).

However, when each opening portion 11X is formed, laser light should be irradiated onto each connecting pad 1 hidden with the mold resin (i.e., the package portion 6) (see FIG. 1). Therefore, it is necessary to additionally form alignment markers. In addition, in order to irradiate laser light with good positional accuracy, an expensive apparatus having a high-precision image recognition device is needed. Otherwise, a deviation x1 may occur even if the center of each opening portion 11X is set to be aligned with that of the associated connecting pad 1 (see FIG. 1).

In the case of using a high-power laser L, the opening portion 11X may not have a desired shape. A part of an edge portion 11a may be shaved. For example, as compared with the edge portion 11a of the desired shape illustrated in FIG. 1, the edge portions 11a illustrated in FIG. 2 are reduced. Thus, a deviation x2 may occur between the height of the surface of the top part of the edge portion 11a from the substrate 2 and the height of the surface of the package portion 6 through the semiconductor chip 4 from the substrate 2 (see FIG. 2).

As illustrated in FIG. 2, a top package 15 is mounted on the bottom package 12X. Then, reflowing is performed. Thus, the bonding material (auxiliary solder) 13 and a connecting bump (solder bump) 18 of the top package 15 are molten. At this time, in the bottom package 12× with the opening portion 11X in which the edge portion 11a is shaved, if an amount of solder molten and joined together is too large, a short-circuit occurs between the connecting bumps 18 of the top package 15.

### SUMMARY

One or more exemplary embodiments of the present invention provide a package in which an opening portion communicating with a connecting pad is formed into a desired shape with good positional accuracy. The above and other objects and novel features of the invention will become apparent from the description in the present specification and the attached drawings.

A method for manufacturing a package according to an exemplary embodiment of the invention, includes preparing a substrate having a first surface on which a connecting pad is formed, mounting a sacrificing material on the connecting pad, forming a package portion covering the first surface of the substrate, exposing the sacrificing material from a surface of the package portion, and removing the exposed sacrificing material from the side of the surface of the package portion, and forming an opening portion in the package portion on the connecting pad.

Advantages obtained by representative aspects of the invention among the aspects of the invention disclosed in the present application are described briefly as follows. That is, a package in which an opening portion communicating with a connecting pad is formed into a desired shape can be provided by removing a sacrificing material. In addition, a package in which an opening portion communicating with a connecting pad is formed with good positional accuracy can be provided by removing a sacrificing material mounted on the connecting pad.

### BRIEF DESCRIPTION OF THE DRAWINGS

The above and other aspects of the present invention will become more apparent from the following description of exemplary embodiments, taken in conjunction with the accompanying drawings of which:

FIG. 1 is a cross-sectional view of a package in a related-art manufacturing process.

FIG. 2 is an enlarged cross-sectional view of the package in a process following the process of FIG. 1.

FIG. 3 is a plan view of a package in a manufacturing process according to a first embodiment of the present invention.

FIG. 4 is a cross-sectional view of the package in a line A-A of FIG. 3.

FIG. 5 is a cross-sectional view of the package in a process following the process of FIG. 4.

FIG. 6 is a cross-sectional view of the package in a process following the process of FIG. 5.

FIG. 7 is a cross-sectional view of the package in a process following the process of FIG. 6.

FIG. 8 is a cross-sectional view of the package in a process following the process of FIG. 7.

FIG. 9 is a cross-sectional view of the package in a process following the process of FIG. 8.

FIG. 10 is a cross-sectional view of a POP structure in a process using the package shown in FIG. 9.

FIG. 11 is a cross-sectional view of the POP structure in a process following the process of FIG. 10.

FIG. 12 is a cross-sectional view of a package in a manufacturing process according to a modified example of the first embodiment of the present invention.

FIG. 13 is a cross-sectional view of a package in a manufacturing process according to a second embodiment of the present invention.

FIG. 14 is a cross-sectional view of a package according to another embodiment of the present invention.

### DETAILED DESCRIPTION

Hereinafter, exemplary embodiments of the invention are described in detail with reference to the drawings. Incidentally, in all drawings illustrating the embodiments, members having the same functions are designated with the same reference numerals, and repetitive description thereof may be omitted.

### Embodiment 1

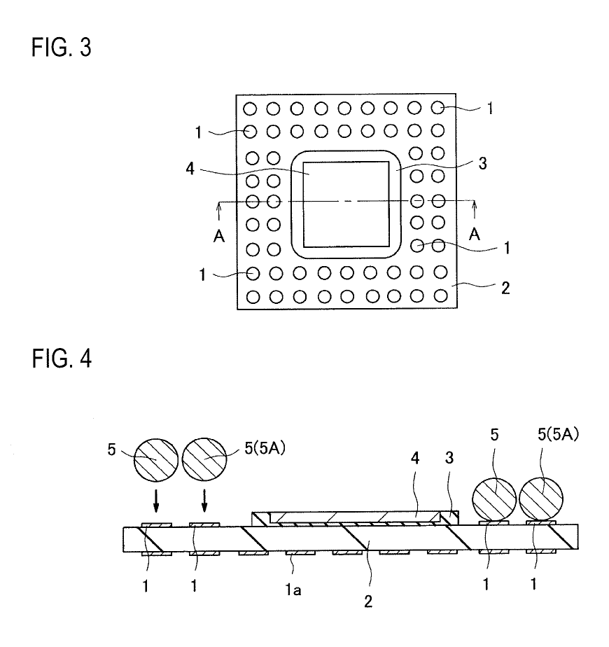

In the present embodiment, a manufacturing method for the bottom package of a POP structure is described with reference to each of steps illustrated in FIGS. 3 to 8. Although the fabrication of multiple bottom-packages on a single-substrate can be achieved using a large-sized substrate as the single-substrate, the manufacturing method is described hereinafter employing a single bottom-package.

First, as shown in FIGS. 3 and 4, a substrate 2 in which connecting pads 1 are formed on the top surface (chip mounting surface) is prepared. Each of the connecting pads 1 serves as a connecting portion of the bottom package. Thus, plural connecting pads are arranged (or formed) around an electronic component (e.g., a semiconductor chip) to be mounted on the substrate 2, without touching the electronic component. The pitch of the adjacent connecting pads 1 is, e.g., about 0.40 millimeters (mm) to 0.50 mm. Then, a semiconductor chip 4 is flip-chip-bonded to the substrate (wiring substrate) 2 through an insulating layer (e.g., an insulating film) 3 on the top surface of the substrate 2.

For example, a wiring substrate having a multi-layer structure manufactured using a buildup method can be used as the substrate 2. An example of the manufacture of a wiring substrate according to the buildup method is described below. First, a core substrate is prepared and insulating layers are formed on both side surfaces of the core substrate. Then, a via hole penetrating through each of the insulating layers is formed. Next, the inside of the via hole is filled with an electrically conductive material and at the same time, a wiring layer is formed on the insulating layer. The insulating layer and the wiring layer are alternately stacked by repeating these steps. Then, e.g., a solder resist film is laminated to cover the topmost wiring layer. Next, an opening portion is formed by patterning the solder resist film to thereby expose the connecting pad. The connecting pad 1 exposed from each solder resist layer (solder resist film) serves as the connecting portion. Thus, copper (Cu), nickel (Ni), and gold (Au) are applied thereto in this order to perform surface treatment.

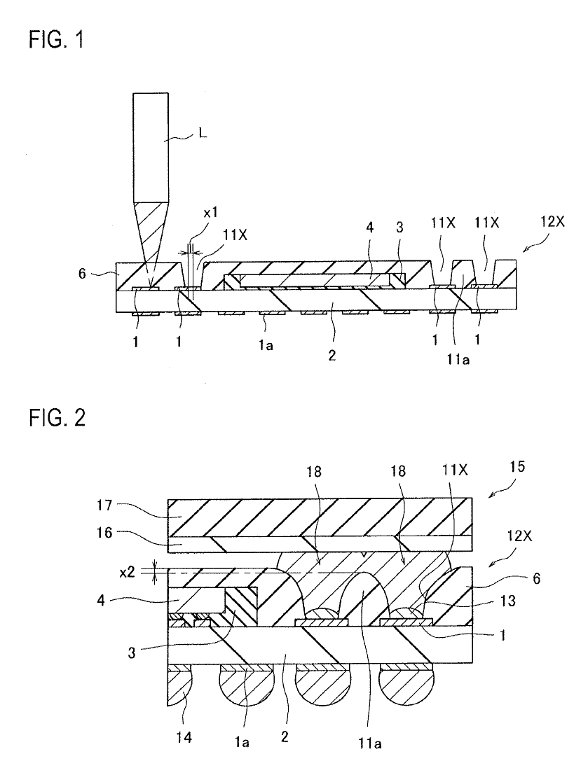

The wiring substrate manufactured in this manner is such that the wiring layers respectively serving as the top-surface-side and bottom-surface-side outermost layers (see FIG. 2) are electrically connected to each other through each inner wiring layer and vias. For example, a glass epoxy wiring substrate is used as the core substrate. For example, a poly-imide-based resin layer and an epoxy-based resin layer are used as the insulating layers. For example, a copper (Cu) layer is used as the wiring layer.

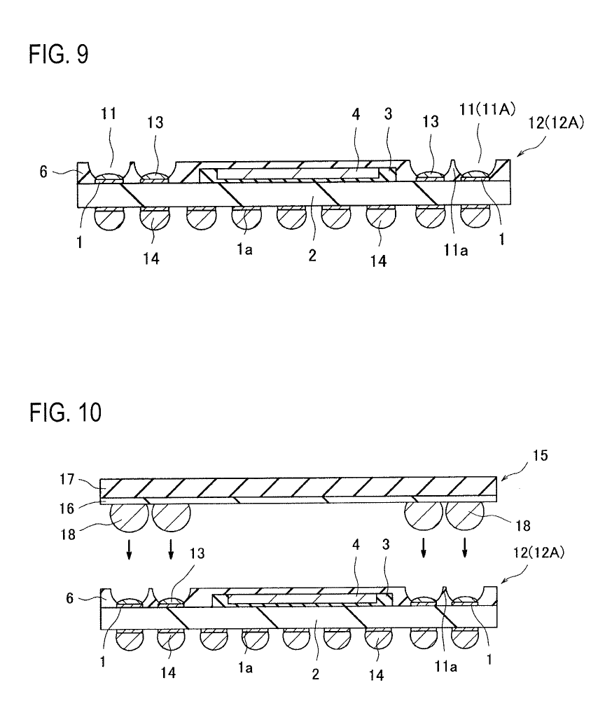

FIG. 4 illustrates connecting pads 1, on each of which a sacrificing material 5 is mounted, at the side of the top surface (mounting surface) of the substrate (wiring substrate) 2, on which the semiconductor chip 4 is mounted, and connecting pads 1a, on each of which a connecting bump 14 (see FIG. 9) is mounted, at the side of the back surface opposite to the top surface. The substrate 2 is not limited to the wiring substrate having the core substrate. A wiring substrate (coreless substrate), which has a multi-layer structure manufactured without using a core substrate, can be used as the substrate 2. The coreless substrate is manufactured by removing a temporary substrate after an insulating layer and a wiring layer are alternately stacked on the temporary substrate.

Subsequently, as illustrated in FIG. 4, the sacrificing materials 5 are mounted on the connecting pads 1, respectively.

The sacrificing material 5 is used for forming an opening portion in the connecting pad 1 in a subsequent step. According to the present embodiment, a spherical sacrificing material 5 is used. More specifically, a solder ball 5A configured by solder is used as the sacrificing material 5. The solder ball 5A is configured by, e.g., solder containing lead (Pb) and tin (Sn), or Pb-free solder containing silver (Ag) and tin (Sn).

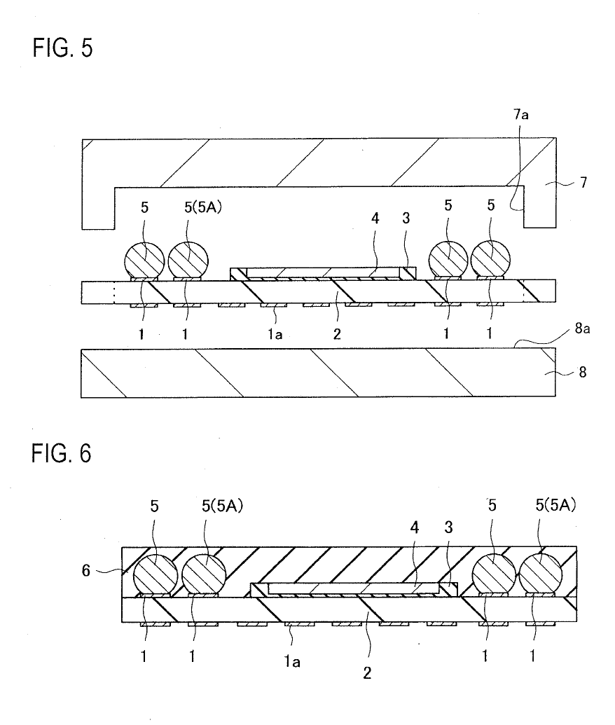

In order to mount the ball 5A on the connecting pad 1, e.g., what is called a dropping method can be used. An example of the dropping method is described hereinafter. First, a mask having plural holes whose positions are aligned with those of the connecting pad 1 is placed on the substrate 2. Then, plural solder balls 5A are dropped into the plural holes, respectively. Thus, each solder ball 5A is put on the associated connecting pad 1 aligned with each hole. Next, heat treatment (reflowing) is performed on the solder balls 5A. Consequently, the molten solder balls 5A are joined to the connecting pads 1, respectively (see FIG. 5).

Thus, the solder balls 5A are mounted on the connecting pads 1, respectively. If flux is used when each connecting pad 1 and the solder ball 5A are joined to each other, residual flux is removed by cleaning.

Next, as illustrated in FIG. 6, a package portion 6 covering a surface of the substrate 2, on which the connecting pads 1 are formed, is formed.

The package portion 6 encloses the semiconductor chip 4 mounted on the substrate 2. According to the present embodiment, a package portion 6 configured by mold resin is formed using a resin mold unit. For example, a thermosetting resin containing filler can be used as the mold resin.

The resin mold unit includes an upper mold 7 having a cavity 7a, which is a mold for the package portion 6, and a lower mold 8 having a clamp surface 8a on which the substrate 2 is placed as shown in FIG. 5. First, the substrate 2 is placed on the clamp surface 8a of the lower mold 8 in a mold opened state. Then, the substrate 2 is clamped by the upper mold 7 and the lower mold 8 by mold-closing. At that time, the top surface (chip mounting surface) of the substrate 2, on which the connecting pads 1 are formed is covered with the cavity 7a. The semiconductor 4 and the solder balls 5A are included by the cavity 7a.

Then, mold resin is injected into the cavity 7a, so that the cavity 7a is filled with the mold resin. After that, the mold resin is heated and thermally-cured. Consequently, a package portion 6 configured by mold resin is formed. Thus, the semiconductor chip 4 and the sacrificing material 5 (i.e., the solder balls 5A) are covered with the package portion 6 (see FIG. 6).

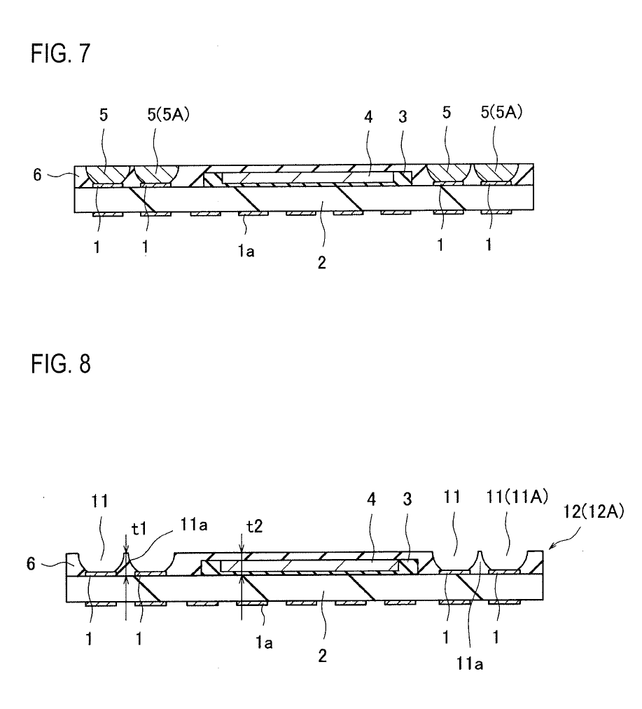

Next, as illustrated in FIG. 7, the sacrificing material 5 (i.e., each solder ball 5A) is exposed from a surface of the package portion 6.

According to the present embodiment, grinding is performed on the surface side of the package portion 6 using a grinder. Thus, the solder balls 5A are exposed from the package portion 6. The grinding is performed until half or more of the height of each solder ball 5A is removed without exposing the semiconductor chip 4. Consequently, each of the solder balls 5A is formed into a bowl-like shape (or a semispherical shape) in which an exposed surface side part thereof is cut off. Further, the semiconductor ship 4 remains being enclosed by the package portion 6.

Next, part of the exposed sacrificing material 5 (each solder ball 5A) is removed from the surface side of the package portion 6. As illustrated in FIG. 8, an opening portion 11 is formed in the package portion 6 on the connecting pad 1. Consequently, a bottom package 12 is substantially completed.

According to the present embodiment, the sacrificing material 5 is removed using etchant. Thus, the opening portion 11 shaped like the sacrificing material 5 is formed. The etchant which has etching selectivity sufficient to remove the sacrificing material 5 from the package portion 6 is used. The package portion 6 is configured by mold resin. The sacrificing material 5 is configured by solder. Therefore, etchant containing methansulfonic acid (whose commercialized product is, e.g., “Melstrip HN-980” manufactured by Meltex Incorporated) can be used. Thus, an opening portion 11 having a desired shape can be formed by removing the exposed sacrificing material 5 using etchant having high etching selectivity between the sacrificing material 5 and the package portion 6.

If an opening portion is formed without providing a sacrificing material, it is necessary to form, e.g., a marker formed on a surface of the package portion, and the opening portion on the connecting pad using a high-precision image recognition device capable of recognizing the marker. On the other hand, according to the present embodiment, an opening portion 11 can be formed with good positional accuracy by removing the exposed sacrificing material 5, even if neither the marker is formed nor the high-precision image recognition device is used when the opening portion 11 is formed. In addition, because it is unnecessary to use an expensive high-precision image recognition device, the manufacturing cost of the package can be reduced.

According to the present embodiment, all of the sacrificing materials 5 (i.e., the solder balls 5A) exposed by grinding are removed. Because each of the ground sacrificing materials 5 has a bowl-like shape (i.e., a semispherical shape), the opening portions 11 have the same shape. That is, each opening portion 11 is formed as a bowl-shaped opening portion 11A having a curved inner wall surface, the opening size of which gradually decreases towards the bottom portion from the inlet part of the opening portion 11.

The bottom package 12 (12A) manufactured through these steps has the package portion 6 covering the top surface of the substrate 2, on which the connecting pads 1 are formed. In the package portion 6, each opening portion 11 communicating with the connecting portion 1 from the surface side thereof is formed. Each opening portion 11 (11A) has the desired shape which is the bowl-like shape (or semispherical shape) and includes the curved inner wall surface.

Each opening portion 11 (11A) is formed like a bowl, so that when a POP structure is manufactured, a bonding material (e.g., solder) joining the connecting pad 1 of the bottom package 12 with the connecting portion of the top package can easily be fixed. If the connecting portion of the top package is, e.g., a connecting bump (solder ball), the opening portion 11 serves as a guide and can lead the connecting bump to the connecting pad 1. Thus, the connecting pad 1 and the connecting bump can surely be abutted on or bonded to each other. Thus, the opening portion 11 of the bottom package 12 can be formed to fit the shape of the connecting portion of the top package.

Next, a manufacturing method for a POP structure using the bottom package 12 is described hereinafter by referring to each of steps illustrated in FIGS. 9 to 11. Incidentally, the POP structure is formed by stacking the top package on the bottom package. Therefore, it can be said that the POP structure is a package as a whole.

First, as illustrated in FIG. 9, a bonding material 13 is formed on the bottom part of the opening portion 11, i.e., on the connecting pad 1. Consequently, the bottom package 12 is configured to have the bonding material 13 formed on the connecting pad 1. The bonding material 13 is configured to bond the connecting pad 1 of the bottom package 12 and the connecting portion of the top package to each other.

According to the present embodiment, solder is used as the bonding material 13. An appropriate amount of the solder is dropped on the connecting pad 1 of the opening portion 11 by a dispenser. Next, molten solder is accumulated on the connecting pad 1 by performing heat treatment (or reflowing) on the solder. Thus, a solder fountain (auxiliary solder) is formed as the bonding material 13.

In addition, as illustrated in FIG. 9, a ball grid array (BGA) structure can be configured by forming a connecting bump 14 (e.g., a solder ball) as a connecting portion on a connecting pad (not shown) exposed from the bottom surface (i.e., a surface opposite to the top surface) of the bottom package 12. Consequently, the bottom package 12 is configured to include the connecting pad 1 as the top-surface-side connecting portion, and to include the connecting bump (BGA structure) 14 as the bottom-surface-side connecting portion. The connecting bump 14 of, e.g., a POP structure is bonded to the connecting portion of a motherboard.

In the case of using a solder ball as each connecting bump 14, the solder ball is mounted on the bottom-surface-side using the above dropping method. Then, heat treatment (reflowing) is performed on the solder ball. Thus, the connecting bump 14 can be formed. Incidentally, heat treatment is performed when the top-surface-side connecting pad 1 and the bonding material 13 are bonded to each other. A treating time can be reduced by performing, simultaneously with the above heat treatment, heat treatment when the bottom-surface-side connecting pad and the bonding material 14 are bonded to each other.

Next, as illustrated in FIG. 10, the top package 15 to be mounted on the bottom package 12 is prepared. The top package 15 includes a substrate 16, an electronic component (not shown) mounted on the substrate 16, a package portion 17 formed on the top-surface-side of the substrate 16 to enclose the electronic component, and connecting bumps 18 formed on the bottom-surface-side of the substrate 16.

The substrate 16 is a wiring substrate formed similarly to the substrate 2. The electronic component is, e.g., a semiconductor chip. The package portion 17 is configured by mold resin formed similarly to the package portion 6. Each connecting bump 18 is a solder ball configuring a BGA structure. The solder ball is mounted on a bottom-surface-side connecting pad (not shown) using the above dropping method. The connecting bump 18 is formed by performing heat treatment (reflowing) on this solder ball.

Incidentally, the diameter (e.g., about 0.25 mm) of the solder ball serving as each connecting bump 18 is smaller than that (e.g., about 0.30 mm) of the solder ball 5A used as the sacrificing material 5. That is, the size of the solder ball (serving as each connecting bump 18) of the top package 15 is smaller than the opening size of the inlet part of the opening portion 11 of the bottom package 12. Consequently, when the top package 15 is mounted on the bottom package 12, each opening portion 11 serves as a guide and can lead the connecting bump 18 to the associated connecting pad 1. Each opening portion 11 is bowl-shaped (or semispherical shape). Thus, each opening portion 11 fits the associated spherical connecting bump 18. Accordingly, the top package 15 is stably mounted on the bottom package 12.

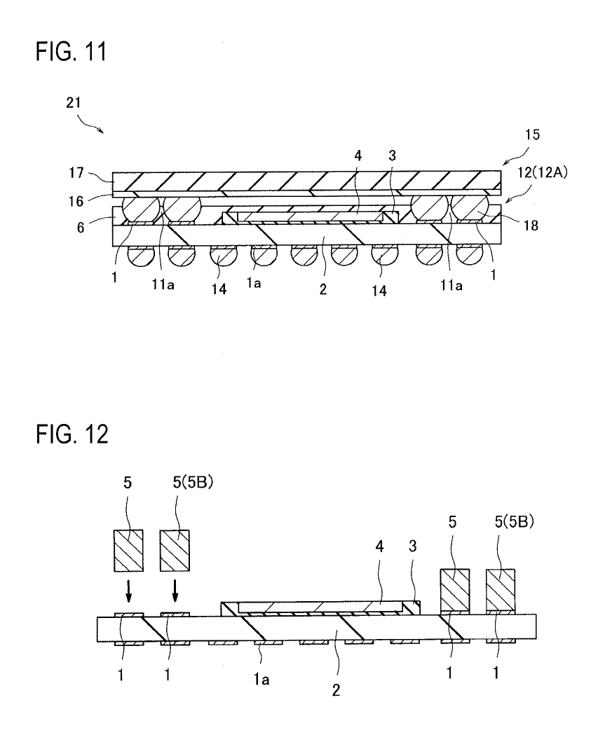

Next, each connecting bump 18 is bonded to the associated connecting pad 1 through the associated molten bonding material 13 (see FIG. 11) by performing heat treatment (reflowing) on the bonding material (auxiliary solder) 13 and the connecting bump (solder ball) 18. The provision of the bonding material 13 facilitates the bonding between the connecting pad 1 and the connecting bump 18. If flux is used when each connecting pad 1 and the associated connecting bump 18 are bonded to each other, residual flux is removed by cleaning.

Thus, as illustrated in FIG. 11, a POP structure 21 configured by stacking the top package 15 on the bottom package 12 is substantially completed.

In the bottom package 12 for the POP structure 21, the edge part 11a of each of adjacent opening portions 11 provided around the semiconductor chip 4 is shared. Each edge part 11a is such that as illustrated in FIG. 8, a height t1 from the substrate 2 to the surface of the top part of the edge part 11a is equal to that t2 from the substrate 2 to the surface of the package portion 6 through the electronic component 4. The reason for the same height t1 and t2 is that each opening portion 11 communicating with the associated connecting pad 1 is formed into a desired shape by the above steps. Thus, the height t1 of the edge part 11a is assured. Accordingly, a short-circuit described with reference to FIG. 2 can be prevented from occurring between the connecting bumps 18 of the top package 15 mounted on the bottom package 12. That is, the manufacturing yield of the POP structure 21 can be enhanced.

In the bottom package 12, the opening portion 11 of each connecting pad 1 is bowl-shaped. Thus, an inner wall surface is formed into a curved shape extending from the bottom portion (a surface of the connecting pad 1). The angle of the inner wall surface of each opening portion 11 with respect to the associated connecting pad 1 is gentle. Thus, even in a case where the inside of each opening portion 11 is filled with solder (electrically-conductive material) by bonding the associated connecting bump 18 to the associated connecting pad 1 through the bonding material 13, a void (or pore) can be prevented from occurring on the surface edge of the connecting pad 1 (i.e., the side of the boundary between the inner wall surface and the connecting pad 1). That is, the reliability of the POP structure 21 can be enhanced.

In the bottom package 12, the opening portion 11 of each connecting pad 1 is bowl-shaped. Thus, the inlet part of the opening portion 11 is larger in opening-size than the bottom part thereof. Accordingly, the bumping of solder can be prevented from occurring when heat treatment (reflowing) is performed to bond each connecting bump (solder ball) 18 to the associated bump 1 through the bonding material (solder fountain) 13. That is, the manufacturing yield of the POP structure 21 can be enhanced.

A modified example of the above embodiment using the solder balls 5A can be accomplished using solder tablets 5B. Hereinafter, a method using solder tablets 5B is described. First, as illustrated in FIG. 12, sacrificing materials 5 (solder tablets 5B) are mounted on the connecting pads 1, respectively.

The sacrificing materials 5 are used in a subsequent step for forming opening portions on the connecting pads 1, respectively. According to the present embodiment, cylindrically-shaped sacrificing materials 5 are used. More specifically, solder tablets 5B configured by solder are used as the sacrificing materials 5. Each solder tablet 5B is configured by, e.g., solder containing lead (Pb) and tin (Sn), or Pb-free solder containing silver (Ag) and tin (Sn).

In order to mount the tablet 5B on the connecting pad 1, e.g., what is called a carrier conveying method can be employed. An example of the carrier conveying method is described hereinafter. First, a carrier is prepared, which has plural suction holes respectively aligned with the positions of the connecting pads 1. Then, one of the circular surfaces of each of plural solder tablets 5B is sucked by an associated one of the plural suction holes. Each solder tablet 5B is placed on the connecting pad 1 aligned with the position of each of the suction holes at the side of the other circular surface thereof. Next, heat treatment (reflowing) is performed on the solder tablets 5B. Consequently, the molten solder tablets 5B are bonded to the connecting pads 1, respectively. Upon completion of the reflowing, each solder tablet 5B is spherical-shaped, similarly to that in the case of mounting the solder balls 5A.

Thus, the solder tablets 5B are mounted on the connecting pads 1, respectively. If flux is used when each connecting pad 1 and the associated solder tablet 5B are joined to each other, residual flux is removed by cleaning.

After that, as illustrated in FIGS. 5 to 8, the package portion 6 covering the surface of the substrate 2, on which the connecting pads 1 are formed, is formed. Then, the sacrificing material 5 (or the solder tablet 5B) is exposed from the surface of the package portion 6. Next, the exposed sacrificing material 5 is removed. Thus, the bottom package 12 having the opening portions 11 is substantially completed.

### Embodiment 2

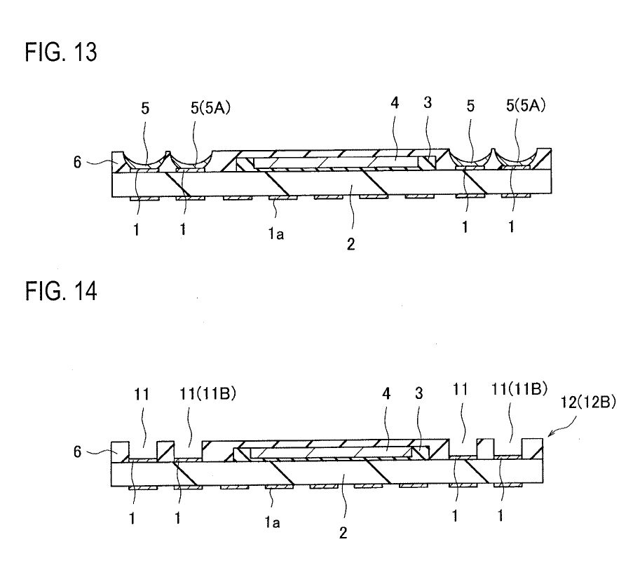

In the above Embodiment 1, the case of dropping an appropriate amount of solder as the bonding material 13 onto the connecting pads 1 in the opening portions 11 by a dispenser has been described. In Embodiment 2, the case of using the sacrificing material 5 (or each solder ball 5A) configured by solder as the bonding material 13 is described hereinafter with reference to a step illustrated in FIG. 13. Other steps according to the present embodiment are the same as described in the above Embodiment 1.

After the step described with reference to FIG. 7, in which the sacrificing materials 5 are exposed from the surface of the package portion 6, as illustrated in FIG. 13, the sacrificing materials 5 are removed using etchant such that a part of each sacrificing material 5 remains. Next, heat treatment (reflowing) is performed on the residual part of each sacrificing material 5 (solder ball 5A) to melt the residual part thereof. The molten solder is accumulated on each connecting pad 1. As illustrated in FIG. 9, a solder fountain (auxiliary solder) is formed as the bonding material 13.

Such a bottom package 12 is configured to include the bonding materials 13 formed on the connecting pads 1. According to the Embodiment 2, it is unnecessary to remove all of the sacrificing materials 5. Thus, a treating time can be shortened. In addition, the step of supplying another material (solder) serving as the bonding material 13 can be omitted.

In the foregoing description, the invention has been described specifically with reference to the embodiments. However, the invention is not limited to the above embodiments. Apparently, various changes of the embodiments can be made without departing from the spirit of the invention.

For example, in the above embodiment, the case of applying a spherically-shaped material (solder ball 5A) to the sacrificing material 5 has been described. The shape of the sacrificing material 5 is not limited thereto. Materials of other shapes such as three-dimensional shapes including a cylindrical shape and a polyhedral shape can be applied to the sacrificing material 5. Thus, each opening portion of the sacrificing material of such a shape can be formed. For example, as shown in FIG. 14, if the opening portion 11B is formed into a cylindrical shape, the bonding material (e.g., solder) bonding between the connecting portions of the bottom package 12B and the top package can easily be fixed when the POP structure is manufactured. For example, if the connecting portion of the top package is a connecting bump, each opening portion 11 serves as a guide and can lead the connecting bump to the connecting pad 1. Thus, the connecting pad 1 and the connecting bump can surely be abutted on and bonded to each other.

The bottom package 12B includes the package portion 6 covering the top surface of the substrate 2 on which the connecting pads 1 are formed. In the package portion 6, each opening portion 11 communicating with the associated connecting pad 1 from the surface side thereof is formed. The opening portion 11 (11B) has a desired shape, i.e., a cylindrical shape. Because of the cylindrical shape of the opening portion 11 (11B), if the connecting portion of the top package is, e.g., a connecting pin (PGA) when the POP structure is manufactured, the opening portion 11 serves as a guide and can lead the connecting pin to the connecting pad 1. Thus, each opening portion 11 of the bottom package 12 can be formed to fit the shape of the connecting portion of the top package.

For example, in the above embodiment, the case of using the solder ball 5A as each spherical sacrificing material 5, and forming the opening portion 11 (11A) on each connecting pad 1 by removing each solder ball 5A has been described. However, the spherical material according to the invention is not limited thereto. It can be considered that a copper (Cu) ball is used as the spherical material. A ferric chloride solution and a copper chloride can be considered as etchant for copper. Even in this case, an opening portion communicating with the connecting pad can be formed with good positional accuracy to have a desired shape.

For example, in the above embodiment, the case of forming the package portion 6 enclosing the semiconductor chip 4 by filling the cavity 7a of the mold (upper mold 7) with mold resin has been described. A method for forming the package 6 according to the invention is not limited thereto. The case of covering the semiconductor chip with sealing-resin (e.g., epoxy resin) by, e.g., potting to enclose the semiconductor chip and form the package portion can be considered. Even in this case, the package portion is formed so as to cover the connecting pads. However, an opening portion communicating with the connecting pad can be formed in the package portion with good positional accuracy into a desired shape by mounting the sacrificing material on the connecting pad to thereby form a package portion, and next removing the sacrificing material.

For example, in the above embodiment, as the explanation with referring to FIG. 7, the case of exposing the sacrificing material 5 from the surface of the package 6 using a grinder has been described. The case of exposing the mode material 5 according to the invention is not limited thereto. Even in this case, the case of exposing the sacrificing material 5 by performing sandblasting thereon from the surface side of the package can be considered. Even in this case, the exposure of the sacrificing material can be performed to remove the sacrificing material.

For example, in the above embodiment, as the explanation with referring to FIG. 7, the case of exposing the sacrificing material 5 covered with the package portion 6, by grinding, from the surface of the package portion 6 has been described. However, the case of exposing the sacrificing material 5 according to the invention is not limited thereto. The package portion can be formed to expose the sacrificing material, without covering the entire sacrificing material. Consequently, no deformation of the sacrificing material due to grinding is caused. Thus, the opening portion can be formed into a more desired shape.

For example, in the above embodiment, the case of removing, by wet etching, the sacrificing material 5 having etching selectivity for the package portion 6 using etchant having this etching selectivity has been described. The method for removing the sacrificing material according to the invention is not limited thereto. The method for removing the sacrificing material 5 according to the invention is not limited thereto. The case of removing, by dry etching having etching selectivity, the sacrificing material 5 can be considered. Because the sacrificing material is exposed, each opening portion communicating with the connecting pad can be formed in the package portion with good positional accuracy. Even in the case of removing the exposed sacrificing material by irradiating a laser-beam thereonto to form an opening portion, the opening portion can be formed with good positional accuracy, because the sacrificing material exposed from the package portion can easily be recognized. If the sacrificing material can be removed by a low-power laser, the opening portion can be formed, which has a desired shape.

For example, in the above embodiment, the case of forming, on the top surface side of the bottom package 12, the package portion 6 configured by mold resin has been described. The case of forming the package portion 6 configured by mold resin according to the invention is not limited thereto. The case of forming, on the bottom surface side of the bottom package, the package portion configured by mold resin, and the case of forming, on the top and bottom surface sides of the bottom package, the package portion configured by mold resin can be considered. When the POP structure is configured, a mold resin portion (package portion) is used to prevent the warpage of the bottom package. Even in the case of forming the mold resin portion on the bottom surface side of the bottom package, the opening portion communicating with the connecting pad can be formed with good positional accuracy to have a desired shape. Thus, the connecting bump can be connected onto the connecting pad with good positional accuracy.

For example, in the above embodiment, the case of enclosing the single semiconductor chip in the packages has been described. The case of enclosing the semiconductor chip according to the invention is not limited thereto. The case of enclosing plural semiconductor chips therein and the case of enclosing other electronic components (e.g., passive components such as a chip capacitor and a resistor) therein can be considered. Even in a case where the density of electronic components mounted on a substrate is high, peripheral opening portions communicating with the connecting pads can be formed with good positional accuracy to have desired shapes.

What is claimed is:

1. A method for manufacturing a package, comprising:
preparing a substrate having a first surface on which a connecting pad is formed;
mounting a sacrificing material on the connecting pad;
forming a package portion covering the first surface of the substrate;
exposing the sacrificing material from a surface of the package portion; and
removing the exposed sacrificing material from surface of the package portion, and forming an opening portion in the package portion on the connecting pad.

2. The package manufacturing method according to claim 1, wherein:
the sacrificing material has high etching selectivity against the package portion, and
the sacrificing material is removed using etchant having the etching selectivity when the sacrificing material is removed so that the opening portion has a shape corresponding to a shape of the sacrificing material.

3. The package manufacturing method according to claim 1, wherein:
the sacrificing material has a spherical shape,
half or more the sacrificing material is removed and exposed by grinding from the surface of the package portion, and
the opening portion is shaped into a bowl having a curved inner wall surface when the sacrificing material is removed.

4. The package manufacturing method according to claim 1, further comprising:
after removing the sacrificing material, performing reflowing to melt a part of the sacrificing material and to form a solder on the connecting pad,
wherein:
the sacrificing material is configured by a solder, and
the sacrificing material is removed to make a part of the sacrificing material remain.

5. The package manufacturing method according to claim 1, wherein the package portion is configured by a mold resin.

6. A package comprising:
a substrate having a first surface on which a connecting pad is formed; and
a package portion being configured by a resin and covering the first surface of the substrate,
wherein the package portion has an opening portion communicating with the connecting pad, and
the opening portion is shaped into a bowl having a curved inner wall surface.

7. The package according to claim 6, further comprising:
an electronic component mounted on the first surface of the substrate,
wherein the package encloses the electronic component,
an edge part of each of the opening portions adjoining with one another around the electronic component is shared, and
a height from the substrate to a surface of a top portion of the edge part is equal to a height from the substrate to the surface of the package portion through the electronic component.

8. The package according to claim 6, further comprising:
a bonding material formed on a bottom portion of the opening portion and on the connecting pad.

9. The package according to claim 6, wherein the package portion is configured by a mold resin.
